(19) United States
(12) Patent Application Publication
(10) Pub. No.: US 2008/0123405 A1
(43) Pub. Date: May 29, 2008

(54) Implanted multi-bit NAND ROM

(76) Inventor: Mammen Thomas, Hercules, CA (US)

Correspondence Address: MAMMEN THOMAS, 103 Schooner Cove, HERCULES, CA, 94547, US

(21) Appl. No.: 11/506,023

(22) Filed: Aug. 18, 2006

(51) Int. Cl. G11C 17/12

(52) U.S. Cl. 365/185.03; 365/185.17; 365/104

(57) ABSTRACT

The market for re-programmable Non-Volatile Memory is growing very fast with the storage of pictures, movies and games. The current NAND technology for mass storage is still limited by density limitations and cost. The volume storage market is composed of applications that require re-programmability and those that are one time programmable. The disclosed technology covers the latter applications like encoded movie storage for distribution. It is more sensitive to the cost that is impacted by die size and technology, and security. The Multi-bit NAND ROM disclosed is programmed by adjusting the Vt implants into the cells to achieve the data status. This allows standard semiconductor technology to be used with no high voltage requirements to store data. The use of the NAND architecture, and multi-bit storage in one storage location, reduce the area of the die and improve the storage density of the device. The information can be encrypted to improve security.

### SUMMARY

The market for re-programmable Non-Volatile Memory is growing very fast with the storage of pictures, movies and games. The current NAND technology for mass storage is still limited by density limitations and cost. The volume storage market is composed of applications that require re-programmability and those that are one time programmable. The disclosed technology covers the latter applications like encoded movie storage for distribution. It is more sensitive to the cost that is impacted by die size and technology, and security. The Multi-bit NAND ROM disclosed is programmed by adjusting the Vt implants into the cells to achieve the data status. This allows standard semiconductor technology to be used with no high voltage requirements to store data. The use of the NAND architecture, and multi-bit storage in one storage location, reduce the area of the die and improve the storage density of the device. The information can be encrypted to improve security.

### FIELD OF INVENTION

The present invention relates to High Volume low cost semiconductor memories, and especially to memories that are programmed at manufacture and are read only.

### BACKGROUND

Currently Non-Volatile memories of the NAND type are used in large volume for mass storage of data. Typical data that gets stored in these memories are of two major types. They are a) where the data is changed during its use period and b) where the data once written is left unchanged for all time.

The Non-Volatile NAND memory is a good candidate for the data that requires change over a period of time like the storage of music and pictures in memories. These get up dated depending on the preferences and inclinations of the individual. The added cost and size restrictions of the memory is overcome by the capability for change when needed and the non-Volatile nature of the memory.

The Non-Volatile NAND memory on the other hand is not really the best memory for volume storage of unchanging data. The fact that the data is not changing once written eliminates a lot of the advantages of using the NAND memory which is mainly oriented at enabling change of data. The additional circuitry and the cost associated with it are being born by the customer who has no need for such a feature. Storage of motion pictures for sale is example of one such market where a one time programmable, lower cost product, will be more suitable.

### PRIOR ART

The NAND Non-Volatile Memory is the prior art of significance. FIG. 1 shows such a memory. It uses a cell that has multiple storage elements (B1 to B4) connected in series, using connect diffusions (7), with a drain select device (A1) and a source select device (A2) as shown, between a drain diffusion (2) and a source diffusion (2x).

The storage elements are typically isolated poly-silicon floating gate devices (having a tunnel gate oxide (9) on silicon in a doped well (1), over which the isolated island of floating gate Poly-silicon (10) is deposed to create a semiconductor device with a channel (8), the conductance of which is controlled by the potential of the floating gate. A control gate typically of poly-silicon (12) over laying the floating gate but isolated from it by an inter-poly dielectric layer (11), typically an ONO (Oxide-Nitride_Oxide) dielectric layer. The control gate is coupled to the floating gate through the ONO. Typical coupling ratios for the present day devices are in the 50% range. During programming and erase high voltage are used on the gate and the well of the devices to supply approximately 10 MEV across the tunnel oxide (9) to cause tunneling of charge from the channel region through the tunnel oxide into the floating gate poly-silicon. This charge is retained in the floating poly-silicon on removal of the high voltage making it a non-volatile memory.

The implementation of the floating gate and the ONO as well as the stack formation with floating gate, ONO and Control gate make the process very complex and completely different from the standard digital or analog CMOS process.

ROMs are read only memories which allow data to be written into the memory and allow only the read out of data. In the past different types of ROMs have been used in the industry. There have been ROMs that were programmable one time after manufacture (OTP Memory), ROMs programmed at diffusion stage of the process, ROMs programmed at metalization stage of the process and also contact stage of the process. There have also been ROMs that used a fuse that can be blown to program the data. A recent addition to this is the One time programmable ROM that use oxide break down as a way to store data in the devices. All these ROMs typically have the NOR structure of memory. NOR type of ROMs are still in use to store information and have a place in the size and cost reduction of the memories. ROMs are used to store the data that does not require change and eliminate the need for high voltages and additional peripheral circuitry to improve density and reduce cost of storage. Typical ROM stores only one bit of Data per cell.

What is Proposed:

What is proposed is a new ROM structure which is architecturally similar to a NAND array and capable of multi-bit storage called the NAND_ROM. The typical NAND array has the advantage of being the smallest size Non-Volatile array possible. This is due to the fact that the NAND cell which forms the array, is a string of multiple storage elements, typically 32 or 64 storage elements, with a source and a drain select device on either side. A cell can hence store multiple bits of data. The disclosed structure is programmed by adjusting the threshold implant into the storage elements during processing to achieve the necessary threshold voltage for each element. By judicial adjustment of the implant dose, multiple threshold distributions are also proposed, providing the multi-bit storage capability in the NAND_ROM. This enable the disclosed NAND_ROM to store more than one bit per element and hence increase the storage capability of each cell and hence the array. Since implant is a very controlled process with tight distribution of doping, it is possible to store even more than two bits per storage element and hence improve the density of storage substantially and hence reduce the cost per bit.

Other major advantages of the NAND_ROM for fixed storage are that it is a low cost standard process with no need for specialized processing for high voltage devices or stacked storage elements. The process can be run in with the standard analog or digital process in the fab with no changes except the Vt implants needed for programming.

The use of the simple technology with minimum size devices improves the yield of manufacture. For a two bit storage element three add on masks which change the Vt of the devices will be needed. These masks will be generated from the data stream to be programmed and can be implemented with data compression and encryption implemented already. This ensures that security features can be implemented effectively. Read back circuitry can be implemented with the capability to decrypt and recover he data in specific machines limiting the use of the information and reducing piracy of data.

### DESCRIPTION OF FIGURES

FIG. 1 Prior art NAND Memory cell

FIG. 2. Typical NAND_ROM cell.

FIG. 3 Implanted multi-bit Vt distribution.

### EXPLANATION OF NUMBERING AND LETTERING IN THE FIGURES

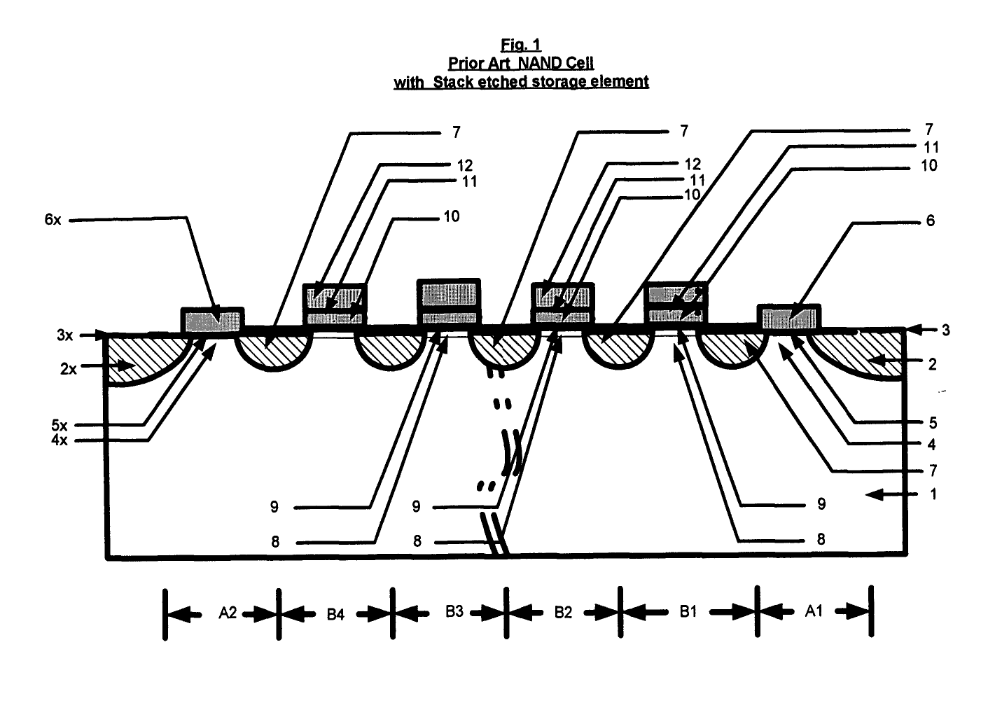

FIG. 1. Prior art NAND Memory cell
1. Implanted P well in silicon substrate.
2. Drain diffusion
2x. Source Diffusion
3. Drain contact area
3x. Source contact area
4. Channel region, in the P-well silicon, of the drain select device
4x. Channel region, in the P-well silicon, of the source select device
5. Gate oxide of the drain select device
5x. Gate oxide of the source select device
6. Gate Poly-silicon of the drain select device
6x. Gate Poly-silicon of the source select device
7. Connect diffusion
8. Channel of storage element
9. Tunnel oxide of the storage element
10. Floating Poly-silicon of the storage element
11. Inter Poly dielectric, typically ONO
12. Control gate Poly-silicon forming the word line
A1. Drain device
A2. Source Device
B1 to B4. Storage elements

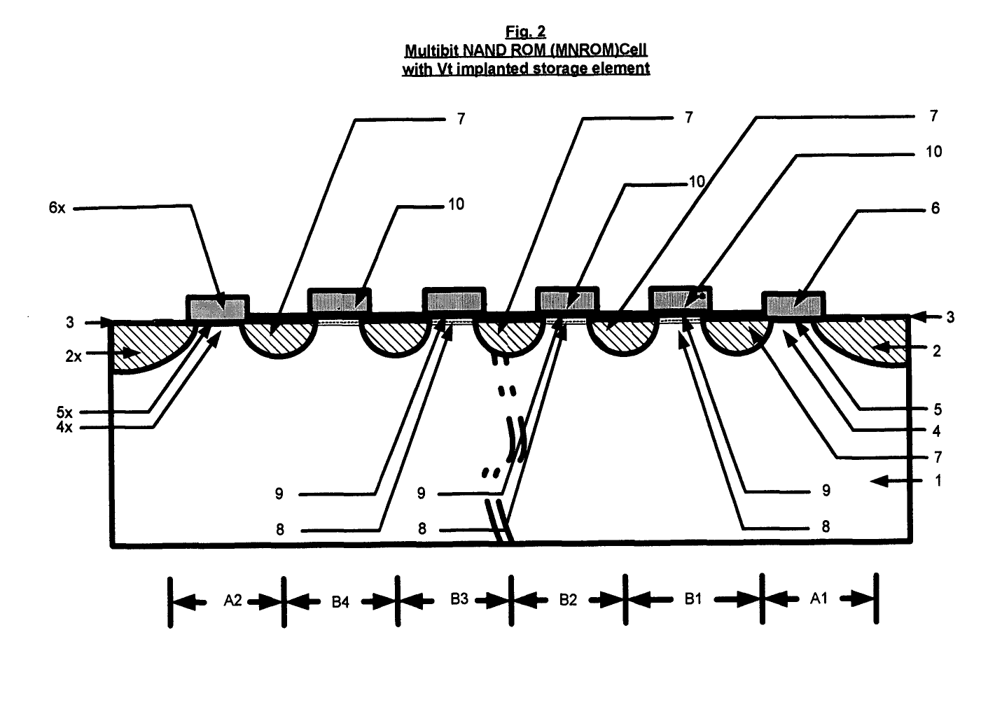

FIG. 2 Multi-bit NAND ROM of the present disclosure
1. Implanted P well in silicon substrate.
2. Drain diffusion
2x. Source Diffusion
3. Drain contact area
3x. Source contact area
4. Channel region, in the P-well silicon, of the drain select device
4x. Channel region, in the P-well silicon, of the source select device
5. Gate oxide of the drain select device
5x. Gate oxide of the source select device
6. Gate Poly-silicon of the drain select device
6x. Gate Poly-silicon of the source select device
7. Connect diffusion
8. Channel of storage element
9. Tunnel oxide of the storage element
10. Floating Poly-silicon of the storage element
A1. Drain device
A2. Source Device
B1 to B4. Storage elements

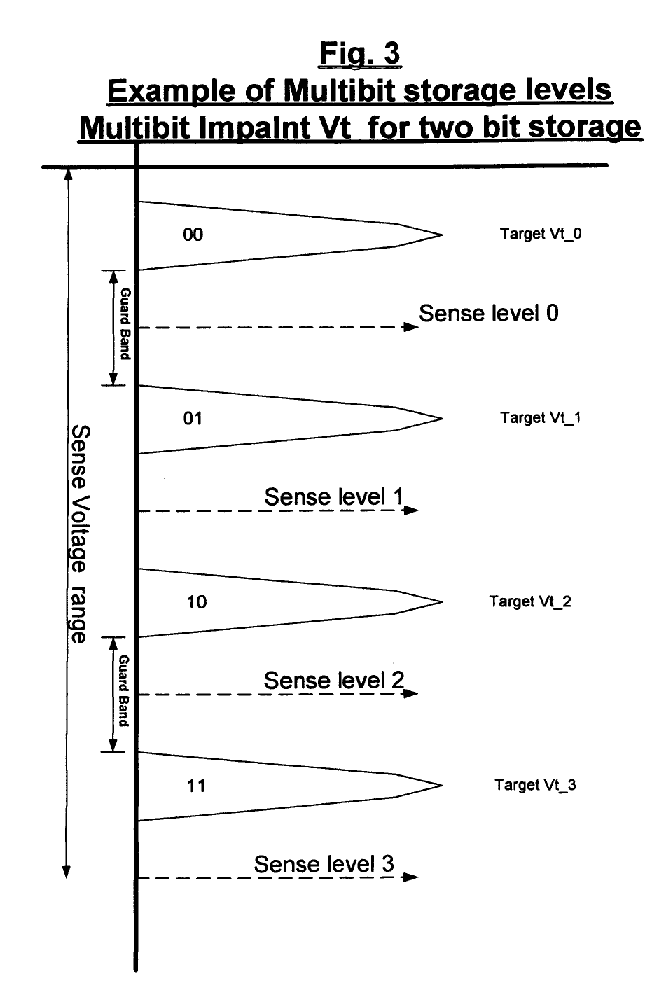

FIG. 3 Vt ranges example for 2 bit storage
Target Vt0 to Target Vt4—Center of the Vt implant levels for the Vt values for storage of two bits “00”, “10”, “01” and “11”.
Sense level—The voltage levels on the gate used to sense the stored level.
Guard band—The separation between the Vt values of each level enabling sense.

### DESCRIPTION OF THE INVENTION

Movie and game storage mainly use the DVD for storage. DVD has the problem of needing heavy accessories like DVD players for play back. The DVDs are also very easily copied leading to piracy and sale of the valuable data. On the other hand the NAND memory that exist today are still too expensive for routine storage of the volume data like movies, but it comes with the advantage that it can be played in any computer or TV and can be installed with barriers and protections against un authorized copying limiting the piracy of movies. The cost and size of the NAND devices have limited their use in these programmable applications which have very large volume and need to be programmed only once. The main reasons for the cost are the process complexity of flash, the yield impact and the need for high voltages and power for program.

The disclosed invention, using the NAND architecture with multi-bit storage capability in an implanted ROM ( NAND ROM) will eliminate most of the problems mentioned. A typical implanted multi-bit NAND ROM cell structure is shown in FIG. 2. Though the shown NAND ROM cell has only four storage elements B1 to B4, it is shown this way for ease of explanation only. The typical NAND ROM structure could have anywhere from 8 to 256 storage elements as a NAND string between a drain select device (A1) and a Source select device (A2) shown in FIG. 2

A P-well (1) in a N-type silicon substrate is typically used as the base for the manufacture of the NAND ROM cell described. All diffusions, the Drain (2), source (2x) and connect diffusions (7) are placed into the well (1) in silicon and are of an opposite dopant type to the well (in this case N-Type) and all gate oxides, gate oxide or the drain select device (5) and the gate oxide of the source select device (5x) as well as the tunnel oxides of the storage elements (9) are grown on the surface of the silicon well. The drain select device (A1) for controlling a drain select channel (4) in the well is formed by deposition and definition of a drain select gate poly-silicon (6) on top of the drain select gate oxide. Similarly the source select device (A2) for controlling a source select channel (4x) in the well is formed by deposition and definition of a source select gate poly-silicon (6x) on top of the source select gate oxide. Each of he storage elements (B1 to B4) for controlling the channel (8) of the storage element in silicon is formed by deposition and definition of the word line poly-silicon over the tunnel oxide of the storage element.

The base structure and polarity of the cell can be changed to a P-type with an N-well and such changes are well understood in the industry and will not be separately described.

Typical NAND Memory cell comprising a NAND string of ‘n’ storage elements or storage devices in series with and between a drain select device and a source select device. The drain select device connects to a drain diffusion contact (3) over a drain diffusion (2) and the source select device connect to a source diffusion contact (3x) over a source diffusion (2x). The inter connection between the drain select device the storage elements in the NAND string and the source select device is by connect diffusions (7). The drain select device and the Source select device each control a channel (4) in a P-well (1) in silicon, by the potential applied to a poly-silicon layer (6 and 6x respectively) that is placed over a gate oxides (5 and 5x), that help isolate the string of storage elements from the drain and source diffusions. Each of the storage elements control a channel (8) in the well in silicon, under a gate oxide (9), over which is a poly-silicon gate. The Threshold of the storage device is adjusted by selective implant during process, based on the data to be stored in the cell. The data is pre processed and converted to the right threshold and the value is used for implant. An example of the implanted thresholds used are shown in FIG. 3. The figure shows two bit storage condition where four separate levels are implanted and sensed to arrive at the value of the two bits. Since implant is a very controlled process and the distribution of the Vt can be adjusted very precisely with minimum spread, it is expected that four or more bits can be stored in a cell with sufficient guard band to reliably read the data, there by improving the density of storage and reducing the cost.

As is clear from the description of the cell, that the cell will be capable of more than two bit storage if the Vt implant spread can be controlled well. It will hence be possible to achieve a higher density of bit storage with a technology node that is not necessarily the most advanced technology node as the gate voltages that can be used are larger.

Arrays of cells are formed by interconnecting the gates of the respective select gates, control gates and storage elements in a word line/ page direction, and interconnecting the drains in a bit line direction to form an addressable array, as is well known in the industry. Typically the source connections are made common for all the cells in the array. Splitting the array into blocks for faster operation due to reduced word line load and reduced bit line load is possible and is also well known to array architects.

The proposed NAND ROM cell requires only standard devices with array Vt implants being the only additional requirement for multiple levels of storage. This makes the memory very cheap and easy to manufacture, especially for volume manufacturing.

The advantages for such a cell for large volume storage of non-changing data are:
1. Once the masks are generated for threshold adjustment and checked the processing can be in volume at low cost.
2. Simple standard silicon processing is sufficient to manufacture the units, reducing the cost and taking advantage of the moors law.
3. Older generation technologies with higher operating voltages may be efficiently used to store and read more bits per cell as the gate swing is more. This can reduce the cost of manufacture.
4. Data can be encrypted for safety.
5. Copying of the information from the silicon is very difficult as there are no visible marks other than the read out information to copy.
6. Data cannot be extracted by standard reverse engineering means.
7. Having capability to have controlled threshold implants allow highly reliable multiple bit data storage in each storage element.
8. Data storage can be highly reliable as multiple implanted thresholds can be adjusted accurately and with minimum degradation with time and operating temperature.
9. Multi-bit storage allows very high density storage capability.
10. Do not need specialized players for read back.
11. Can be configured for use in any type of display unit, example computers or TV.
12. Small and easy to transport volume data.
13. Limitation to use with specific read modules pre-installed of a preferred type with internal decodes and security can be used to reduce piracy.
14. The use of pre-installed modules will also prevent unwanted usage in other units without the decode module.

What is claimed is:

1. An Implanted NAND ROM memory cell comprising a NAND string of ‘n’ storage elements in series with and between a drain select device and a source select device deposed between a drain diffusion and a source diffusion in a diffused well in silicon.

2. The Implanted NAND ROM memory cell comprising a NAND string of ‘n’ storage elements in series with and between a drain select device and a source select device deposed between a drain diffusion and a source diffusion in a diffused well in silicon of claim 1, where in, the storage elements and select devices are P-channel elements and devices in a diffused N-well.

3. The Implanted NAND ROM memory cell comprising a NAND string of ‘n’ storage elements in series with and between a drain select device and a source select device deposed between a drain diffusion and a source diffusion in a diffused well in silicon of claim 1, where in, the storage elements and select devices are N-channel elements and devices in a diffused P-well.

4. The Implanted NAND ROM memory cell comprising a NAND string of ‘n’ storage elements in series with and between a drain select device and a source select device deposed between a drain diffusion and a source diffusion in a diffused well in silicon of claim 1, where in, the storage elements are standard semiconductor devices with implanted threshold adjustment for fixing data levels.

5. An implanted NAND ROM memory cell comprising the NAND string of ‘n’ storage elements in series where the data is stored in the memory element as a threshold value.

6. The implanted NAND ROM memory cell comprising the NAND string of ‘n’ storage elements in series in claim 5, where in, multiple threshold levels allow Multiple bits of data to be stored in a single element.

7. The implanted NAND ROM memory cell comprising the NAND string of ‘n’ storage elements in series in claim 5, where in, the implant masks can be used to implant and adjust thresholds of storage elements.

8. The implanted NAND ROM memory cell comprising the NAND string of ‘n’ storage elements in series in claim 5, where in, having capability to have controlled threshold implants allow highly reliable multiple bit data storage in each storage element.

9. An Implanted NAND ROM memory comprising an array of NAND strings where standard silicon processing with multiple threshold implants for multi-bit storage is used to manufacture the units.

10. The Implanted NAND ROM memory comprising an array of NAND strings where standard silicon processing with multiple threshold implants in claim 9, where in, very high memory density can be achieved by multiple bit storage per element.
